(19) United States
(12) Patent Application Publication
(10) Pub. No.: US 2024/0087944 A1
(43) Pub. Date: Mar. 14, 2024

(54) SYSTEM AND APPARATUS FOR A LIFT PIN

(71) Applicant: ASM IP Holding B.V., Almere (NL)

(72) Inventors: George Brad Jackson, Phoenix, AZ (US); Rohan Rajeev Puranik, Tempe, AZ (US); Todd Robert Dunn, Cave Creek, AZ (US); Yingzong Bu, Powell, OH (US); Ruchik Jayeskumar Bhatt, Chandler, AZ (US)

(21) Appl. No.: 18/243,173

(22) Filed: Sep. 7, 2023

Related U.S. Application Data
(60) Provisional application No. 63/405,805, filed on Sep. 12, 2022.

(51) Int. Cl. H01L 21/687

(52) U.S. Cl. CPC H01L 21/68742

(57) ABSTRACT

A lift pin assembly includes a holder to engage and secure the lift pin and a bellow to actuate the lift pin and the holder linearly and vertically. The holder includes three pieces that connect together to secure the lift pin within the holder. The holder includes a first piece having a recessed area, a second piece that nests within the recessed area, and a third piece adjacent the first and second pieces. The second piece contains a threaded hole to receive and secure the lift pin and the third piece contains a through-hole that aligns with the threaded hole of the second piece.

### FIELD OF THE DISCLOSURE

This application is a nonprovisional of, and claims priority to and the benefit of, U.S. Provisional Patent Application No. 63/405,805, filed Sep. 12, 2022 and entitled “SYSTEM AND APPARATUS FOR A LIFT PIN,” which is hereby incorporated by reference herein.

### FIELD OF THE DISCLOSURE

The present disclosure relates generally to methods and systems utilizing lift pins to lift wafers from susceptors in a wafer processing or reactor system, and, more particularly, to methods and apparatus for securing and mechanically operating the lift pins relative to the susceptor in a semiconductor processing or reactor system.

### BACKGROUND OF THE DISCLOSURE

Semiconductor processing techniques, including atomic layer deposition (ALD) and chemical vapor deposition (CVD), are often used for forming thin films of materials on substrates, such as silicon wafers. To carry out such processing, reactor systems or tools are used that have a reaction chamber in which a susceptor or substrate holder is positioned and used for holding wafers during wafer processing steps.

In some reaction system designs lift pins that extend upward through the susceptor are used to facilitate unloading of wafers by extending a distance above the upper surface of the susceptor. In some cases, the susceptor is stationary and the lift pins move relative to the susceptor so that the lift pins extend above the upper surface of the susceptor (the up position). When the lift pins are in the down position, they are retracted to be positioned flush with the upper surface of the susceptor or below the upper surface of the susceptor.

Due to several factors, the wafer lift pins in reactor systems or apparatus can become stuck in the up position. In this undesirable operation condition, the head of the lift pin protrudes above the susceptor pocket position when it should be fully retracted below the surface. The may result in a tilted wafer caused by a stuck lift pin(s), which can cause non-uniform deposition due to a non-uniform or undesired wafer temperature profile and uneven gas distribution created by the tilted wafer.

### SUMMARY OF THE DISCLOSURE

Embodiments of the present disclosure provide a lift pin assembly having a holder to engage and secure the lift pin and a bellow to actuate the lift pin and the holder a linearly and vertically. The holder includes three pieces that connect together to secure the lift pin within the holder. The holder includes a first piece having a recessed area, a second piece that nests within the recessed area, and a third piece adjacent the first and second pieces. The second piece contains a threaded hole to receive and secure the lift pin and the third piece contains a through-hole that aligns with the threaded hole of the second piece.

In one aspect, an apparatus comprises a lift pin comprising a first end and a second end opposite the first end, wherein the first end and the second end define a z-axis of the lift pin, and wherein the second end is threaded; an assembly comprising: a first mechanism arranged a first end of the assembly and comprising a hole configured to engage the second end of the lift pin; a second mechanism arranged at the second end of the assembly and coupled to the first mechanism, wherein the second mechanism is configured to move the first mechanism along z-axis of the lift pin; a platform positioned adjacent to the second mechanism; and a connector extending through the platform and the second mechanism, and connected to the first mechanism.

In another aspect, a holder for a lift pin comprises a first piece comprising a recessed area; a second piece is sized to nest within the recessed area and comprises a threaded hole adapted to engage with the lift pin; and a third piece positioned adjacent the first piece and the second piece, and comprising a through-hole aligned with the threaded hole.

In yet another aspect, a system comprises a reaction chamber comprising an interior space; a susceptor disposed in the interior space and comprising a plurality of through-holes; and a sub-system comprising a plurality of lift pin assemblies connected to an actuator, wherein each lift pin assembly comprises: a lift pin extending through one through-hole of the susceptor, the lift pin comprising a first end and a threaded, second end opposite the first end; a first mechanism comprising: a first piece comprising a recessed area and a bore opposite the recessed area; a second piece disposed within the recessed area, the second piece comprising a threaded hole configured to engage the threaded, second end of the lift pin; and a third piece adjacent the second piece and comprising a through-hole aligned with the threaded hole of the second piece; a second mechanism coupled to the first mechanism, wherein the second mechanism is configured to expand and contract in response to the actuator; and a connector extending through the second mechanism and connected to the bore and the actuator.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIGS. 1A and 1B representatively illustrates a reactor system in accordance with an embodiment of the present technology;

FIG. 2 is a lift pin assembly in accordance with an embodiment of the present technology;

FIG. 3 is a cross sectional view of a portion of the lift pin assembly in accordance with an embodiment of the present technology;

FIG. 4 is a cross sectional view of the lift pin assembly in accordance with an embodiment of the present technology;

FIG. 5 is an exploded perspective view of a lift pin holder in accordance with an embodiment of the present technology;

FIG. 6 is an exploded alternative view of the lift pin holder in accordance with an embodiment of the present technology; and

FIG. 7 is a top view of a portion of the lift pin holder in accordance with an embodiment of the present technology.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As described in greater detail below, various details and embodiments of the disclosure may be utilized in conjunction with a reactor system with one or more reaction chambers configured for a multitude of deposition processes, including but not limited to, ALD, CVD, metalorganic chemical vapor deposition (MOCVD), molecular beam epitaxy (MBE), physical vapor deposition (PVD), plasma-enhanced chemical vapor deposition (PECVD), and plasma etching. The embodiments of the disclosure may also be utilized in semiconductor processing systems configured for processing a substrate with a reactive precursor, which may also include etch processes, such as, for example, reactive ion etching (RIE), capacitively coupled plasma etching (CCP), and electron cyclotron resonance etching (ECR).

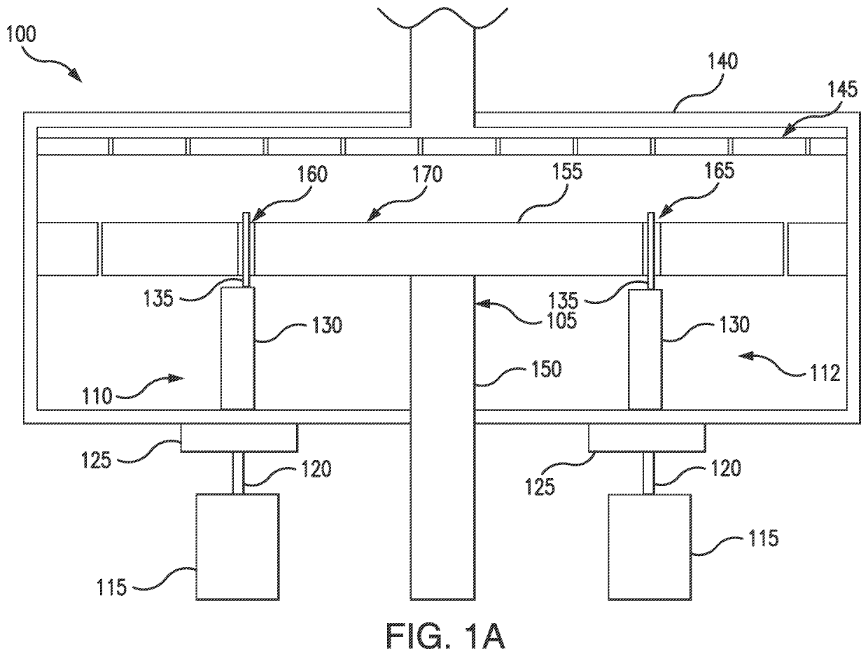

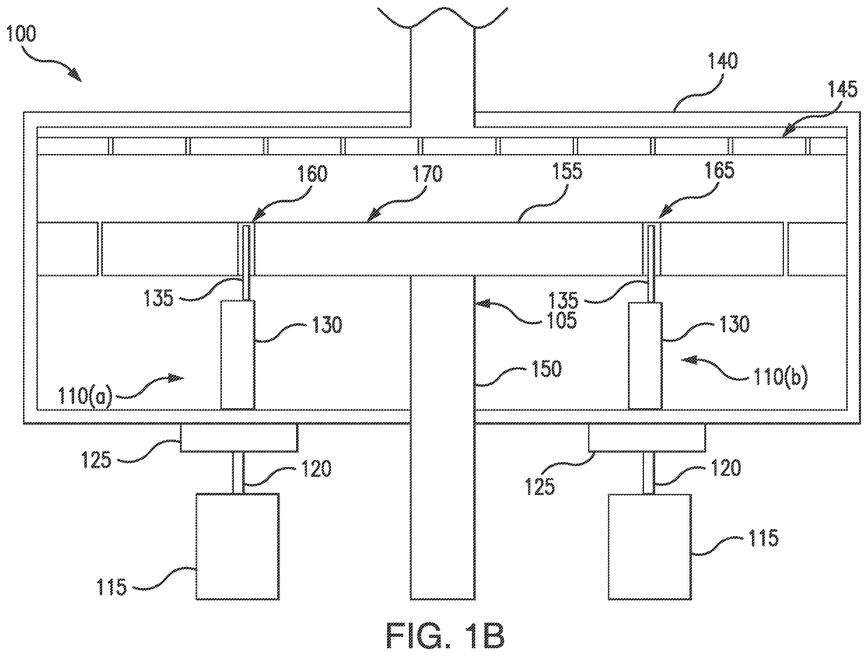

Referring to FIGS. 1A and 1B, an exemplary system 100 may comprise a reaction chamber 140 having an interior space to receive a wafer (not shown) and configured to perform a desired process or processing on the wafer.

In various embodiments, the system 100 may further comprise a susceptor 105 arranged in the interior space. The susceptor 105 may comprise a pedestal 150 attached to and supporting a wafer support 155. During use, a wafer may be placed on a top surface 170 of the wafer support 155. The wafer support 155 may comprise a plurality of through-holes, such as a first through-hole 160 and a second through-hole 165. In various embodiments, the wafer support 155 may be formed of ceramic (alumina, AlOx) or a metal, such as stainless steel, titanium, or the like.

In various embodiments, the system 100 may comprise a gas distribution plate 145 (e.g., a showerhead) configured to distribute gas and disposed within the interior space of the reaction chamber 140 and above the susceptor 105. In various embodiments, the gas distribution plate 145 may comprise a plurality of through-holes.

In various embodiments, the system 100 may further comprise a lift pin assembly 110 configured to assist in loading the wafer onto the wafer support 155 and unloading the wafer off of the wafer support 155. In many cases, the system 100 may comprise a plurality of lift pin assemblies, such as three, four, etc., arranged equidistant from each other. The lift pin assembly 110 may be arranged below the wafer support 155—i.e., opposite from the top surface 170 of the wafer support 155. The lift pin assembly 110 may be configured to extend through and move through the through-holes 160, 165. For example, a first lift pin assembly 110(a) may extend and move through the first through hole 160 and the second lift pin assembly 110(b) may extend and move through the second through-hole 165. In a first position, and referring to FIG. 1A, the lift pin assemblies 110(a/b) may extend above the top surface 170 of the wafer support 155. In a second position, and referring to FIG. 1B, the lift pin assemblies 110(a/b) may be recessed below the top surface 170 of the wafer support or flush with the top surface 170.

In an exemplary embodiment, the lift pin assembly 110 may comprise a lift pin 135 and a sub-assembly 130. The lift pin 135 may engage with and connect to the sub-assembly 130. In various embodiments, the lift pin 135 may be substantially cylindrically-shaped and have a diameter that is smaller than a diameter of the through-hole 160, 165. The lift pin 135 may comprise a first end 300 and a second end 305. The first end may extend through the through-hole 160, 165. The second end 305 may comprise a threaded portion to engage with the sub-assembly 130. The lift pin 135 may be formed of ceramic (alumina, AlOx) or a metal such as Hastelloy, stainless steel, or the like.

In various embodiments, the lift pin assembly 110 may further comprise a seal 125 positioned on an outer surface of the reaction chamber 140. Specifically, the seal 125 may directly contact a bottom, outward facing surface of the reaction chamber 140. The seal 125 may be configured to secure the sub-assembly 130 to the reaction chamber 140.

In various embodiments, the lift pin assembly 110 may further comprise a rod 120 configured to push and pull the sub-assembly 130 upwards and downwards. The rod 120 may be connected to an actuator 115 or other suitable mechanical device or system to actuate the rod 120. In various embodiments, the rod 120 may comprise a threaded end. The rod 120 may be constructed of a metal, such as Hastelloy, stainless steel, or the like.

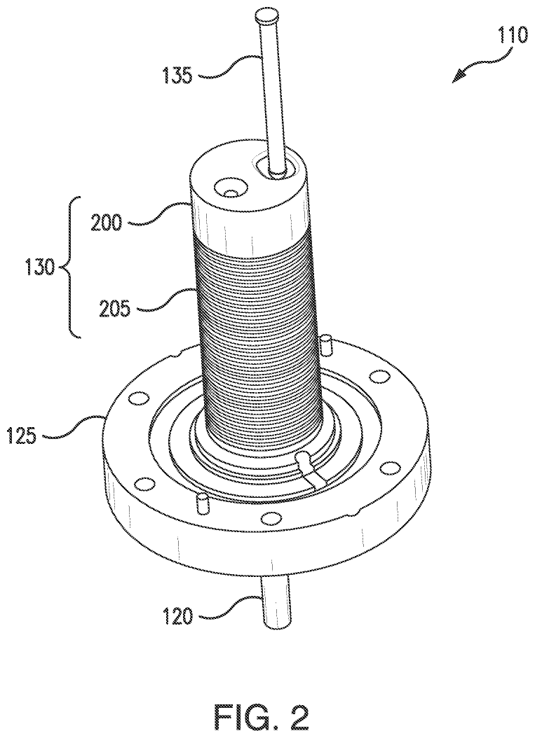

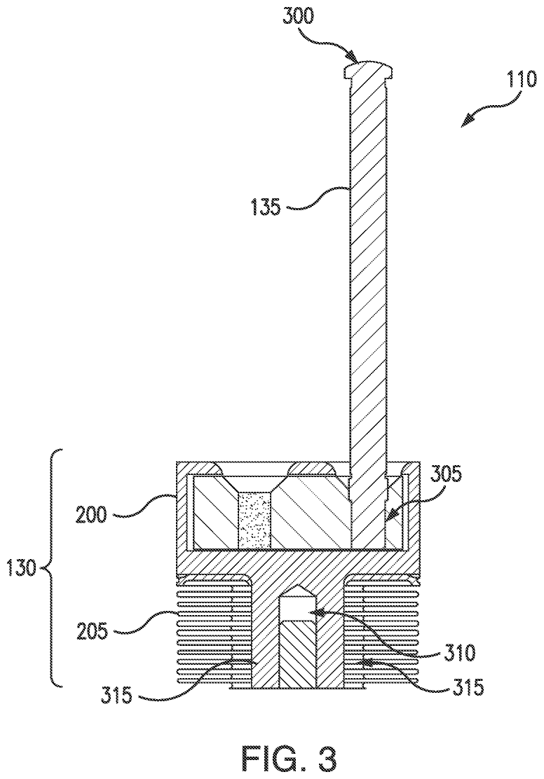

In an exemplary embodiment, and referring to FIGS. 2 and 3, the sub-assembly 130 may comprise a holder 200 arranged at a first end and a bellow 205 arranged at a second end. The holder 200 may be coupled to the bellow 205. For example, the holder 200 may be configured to mate with the bellow 205.

The bellow 205 may comprise an actuator (not shown) disposed in an interior portion of the bellow 205 to expand and contract the bellow 205 in a linear and vertical manner. The bellow 205 may further comprise an inner core 320 to mate with the holder 200.

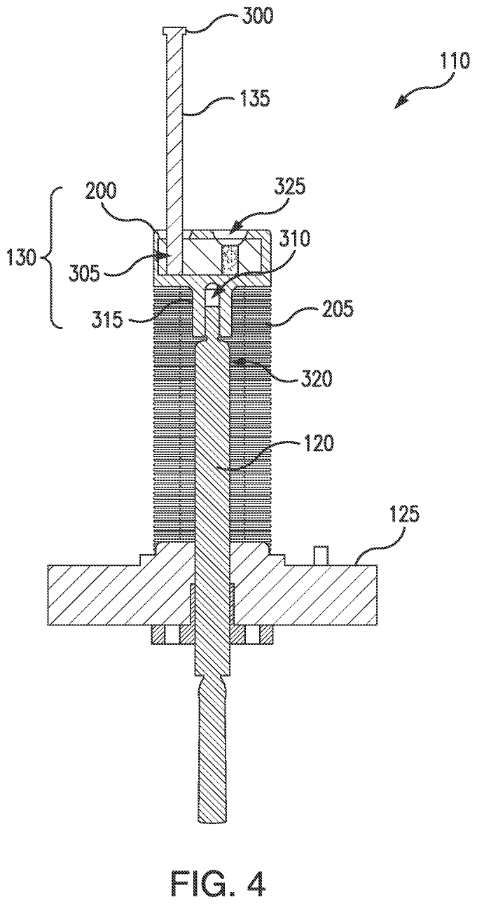

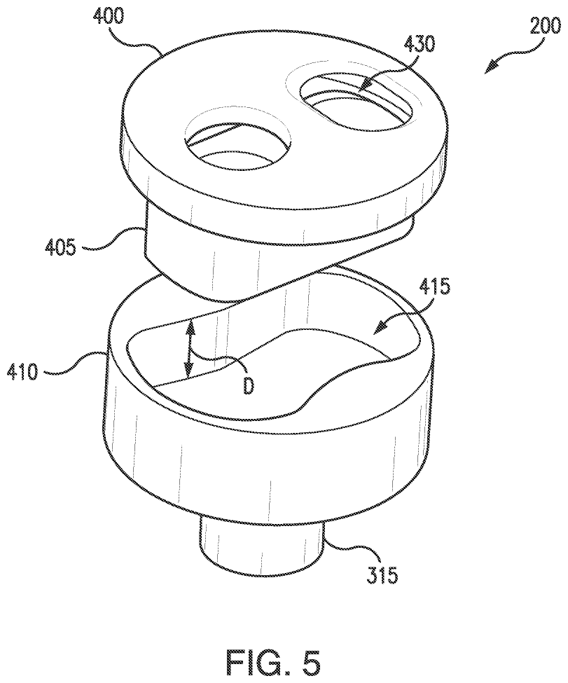

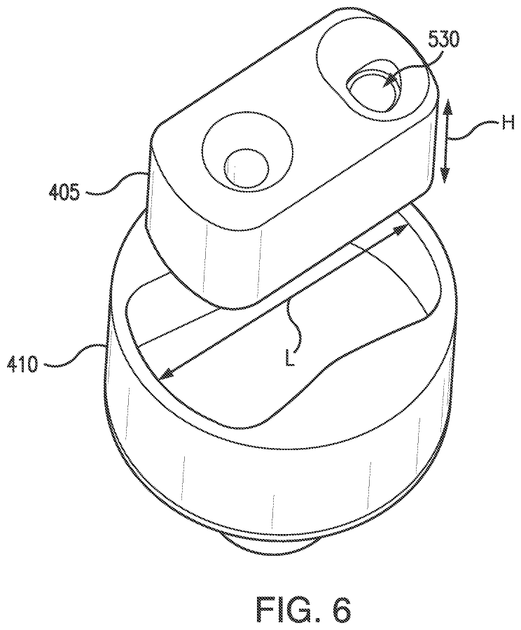

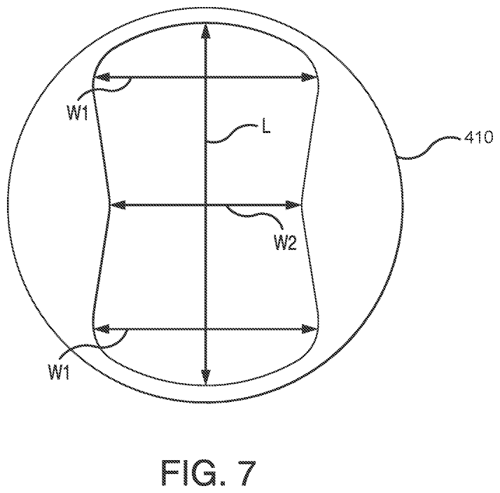

In an exemplary embodiment, and referring to FIGS. 3-7, the holder 200 may comprise multiple pieces that connect together to allow the holder 200 to secure the lift pin 135 and couple to the bellow 205. For example, the holder 200 may comprise a first piece that engages with the inner core 315 of the bellow 205. The first piece 410 may comprise an arm 315 extending away from a bottom end of the first piece 410. The arm 315 may comprise a bore 310 arranged vertically in the arm 315 and perpendicular to the bottom end of the first piece 410. In various embodiments, the rod 120 extends through the bellow 205 and engages with the bore 310. For example, the rod 120 may mate with the bore 310 via threaded sections of the rod 120 and bore 310.

The first piece 410 may further comprise a recessed area 415, opposite the arm 315. The recessed area 415 may have a depth D in the range of 3 mm to 10 mm (e.g., 6 mm) and a length L in the range of 15 mm to 30 mm (e.g., 24 mm). The recessed area 415 may have a first end having a first width W1 in the range of 10 mm to 20 mm (e.g., 14.9 mm) and a second end having the same width. The recessed area 415 may have a middle section located between the first end and the second end, wherein the middle section has a second width W2 in the range of 8 mm to 16 mm (e.g., 12.6 mm) that is less than the first width W1 of the first and second ends. The first piece 410 may be formed of a metal, such as Hastelloy, stainless steel, or the like, using any suitable machining techniques and/or 3D printing.

In an exemplary embodiment, the holder 200 may further comprise a second piece 405 sized to nest within the recessed area 415. For example, the second piece 405 may have a length and width that is smaller than the length 500 and width of the recessed area. The second piece 405 may have a height H that is less than or equal to the depth D of the recessed area 415. In an exemplary embodiment, the second piece 405 comprises two opposing sidewalls that are parallel to each other. Accordingly, the second piece 405 is a different shape than the recessed area 415. This difference in shape allows the second piece 405 to rotate within the recessed area 415 by up to +/−5 degrees. The second piece 405 may further comprise a threaded hole 530. The threaded hole 530 may be threaded to mate with the threaded end of the lift pin 135. The second piece 405 may be formed of such as Hastelloy, stainless steel, or the like, using any suitable machining techniques and/or 3D printing.

In an exemplary embodiment, the holder 200 may further comprise a third piece 400 may overlay the first and second pieces 410, 405. The third piece 400 may be configured to fasten to the first piece 410, for example, the third piece 400 may be configured to screw onto the first piece 410 or may be coupled to the first piece 410 using an adhesive, bonding material (such as by welding), or other suitable material. The third piece 400 is arranged adjacent to the second piece 405, but not fixed to the second piece 405. In other words, the third piece 400 may be used to contain the second piece 405 within the recessed area 415 while allowing the second piece 405 to move freely within the recessed area 415 without restriction. In other words, the second piece 405 is limited only by the dimensions (e.g., sidewalls and width W1) of the recessed area 415. The third piece 400 may further comprise a through-hole 430 that aligns with the threaded hole 530 of the second piece 405. The third piece 400 may be formed of such as Hastelloy, stainless steel, or the like, using any suitable machining techniques and/or 3D printing.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Reference throughout this specification to features, advantages, or similar language does not imply that all of the features and advantages that may be realized with the present disclosure should be or are in any single embodiment of the invention. Rather, language referring to the features and advantages is understood to mean that a specific feature, advantage, or characteristic described in connection with an embodiment is included in at least one embodiment of the subject matter disclosed herein. Thus, discussion of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S.C. 112(f) unless the element is expressly recited using the phrase “means for.”

The scope of the disclosure is to be limited by nothing other than the appended claims, in which reference to an element in the singular is not intended to mean “one and only one” unless explicitly so stated, but rather “one or more.” It is to be understood that unless specifically stated otherwise, references to “a,” “an,” and/or “the” may include one or more than one and that reference to an item in the singular may also include the item in the plural. Further, the term “plurality” can be defined as “at least two.” As used herein, the phrase “at least one of”, when used with a list of items, means different combinations of one or more of the listed items may be used and only one of the items in the list may be needed. The item may be a particular object, thing, or category. Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C.

All ranges and ratio limits disclosed herein may be combined. Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Any reference to attached, fixed, connected or the like may include permanent, removable, temporary, partial, full and/or any other possible attachment option. Additionally, any reference to without contact (or similar phrases) may also include reduced contact or minimal contact. In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. An apparatus, comprising:
a lift pin comprising a first end and a second end opposite the first end, wherein the first end and the second end define a z-axis of the lift pin, and wherein the second end is threaded;
an assembly comprising:
a first mechanism arranged a first end of the assembly and comprising a hole configured to engage the second end of the lift pin;
a second mechanism arranged at the second end of the assembly and coupled to the first mechanism, wherein the second mechanism is configured to move the first mechanism along z-axis of the lift pin;
a platform positioned adjacent to the second mechanism; and
a connector extending through the platform and the second mechanism, and connected to the first mechanism.

2. The apparatus according to claim 1, wherein the first mechanism comprises a first piece comprising a recessed area.

3. The apparatus according claim 2, wherein the first piece further comprises cylindrical section opposite the recessed area, wherein the cylindrical section comprises a bore opposite the recessed area.

4. The apparatus according to claim 2, wherein the first mechanism further comprises a second piece nested within the recessed area.

5. The apparatus according to claim 4, wherein the second piece comprises a first through-hole having a diameter that is larger than a diameter of the lift pin, wherein the first through-hole is threaded to mate with the threaded, second end of the lift pin.

6. The apparatus according to claim 5, wherein the first mechanism further comprises a third piece positioned adjacent the first piece and the second piece, wherein the third piece comprises a second through-hole that aligns with the first through-hole.

7. The apparatus according to claim 1, wherein the first mechanism comprises a first piece comprising a recessed area, wherein the recessed area comprises:
a first end section having a first width;
a second end section having a second width; and
a middle section positioned between the first end section and the second end section, and having a third width;
wherein the first and second widths are the same and the third width is less than the first and second widths.

8. The apparatus according to claim 7, wherein the first mechanism further comprises a second piece having a single, constant fourth width that is less than the third width.

9. The apparatus according to claim 1, wherein the second mechanism comprises bellows.

10. A holder for a lift pin comprising:
a first piece comprising a recessed area;
a second piece is sized to nest within the recessed area and comprises a threaded hole adapted to engage with the lift pin; and
a third piece positioned adjacent the first piece and the second piece, and comprising a through-hole aligned with the threaded hole.

11. The holder according to claim 10, wherein the recessed area comprises:
a first end section having a first width;
a second end section having a second width; and
a middle section positioned between the first end section and the second end section, and having a third width, wherein the first and second widths are the same and the third width is less than the first and second widths.

12. The holder according to claim 11, wherein the second piece has a single, constant fourth width that is less than the third width.

13. The holder according to claim 10, wherein the first piece further comprises cylindrical section opposite the recessed area, wherein the cylindrical section comprises a bore opposite the recessed area.

14. The holder according to claim 10, wherein the second piece is sized to rotate laterally within the recessed area.

15. A system, comprising:
a reaction chamber comprising an interior space;
a susceptor disposed in the interior space and comprising a plurality of through-holes; and
a sub-system comprising a plurality of lift pin assemblies connected to an actuator,
wherein each lift pin assembly comprises:
a lift pin extending through one through-hole of the susceptor, the lift pin comprising a first end and a threaded, second end opposite the first end;
a first mechanism comprising:
a first piece comprising a recessed area and a bore opposite the recessed area;
a second piece disposed within the recessed area, the second piece comprising a threaded hole configured to engage the threaded, second end of the lift pin; and
a third piece adjacent the second piece and comprising a through-hole aligned with the threaded hole of the second piece;
a second mechanism coupled to the first mechanism, wherein the second mechanism is configured to expand and contract in response to the actuator; and
a connector extending through the second mechanism and connected to the bore and the actuator.

16. The system according to claim 15, wherein the recessed area comprises:
a first end section having a first width;
a second end section having a second width; and
a middle section positioned between the first end section and the second end section, and having a third width;
wherein the first and second widths are the same and the third width is less than the first and second widths.

17. The system according to claim 16, wherein the second piece has a single, constant fourth width that is less than the third width.

18. The system according to claim 15, wherein the actuator is configured to exert a first force and a second, opposite force on the connector.

19. The system according to claim 15, wherein the second mechanism comprises bellows.

20. The system according to claim 15, wherein the second piece is sized to rotate laterally within the recessed area.
